(19) United States
(12) Patent Application Publication
(10) Pub. No.: US 2010/0090334 A1
(43) Pub. Date: Apr. 15, 2010

(54) Electronic Part Manufacturing Method

(75) Inventor: Mutsumi MASUMOTO, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/637,420

(22) Filed: Dec. 14, 2009

Related U.S. Application Data
(63) Continuation of application No. 11/551,476, filed on Oct. 20, 2006.

(30) Foreign Application Priority Data
Oct. 20, 2005 (JP) 2005305131

(51) Int. Cl. H01L 23/48; B23K 31/02

(52) U.S. Cl. 257/693; 228/199; 257/E23.01

(57) ABSTRACT

The objective of this invention is to prevent the generation of defects pertaining to placement of solder balls on the terminal placement parts of the electronic part main body. The solder ball 1 has spherical core 2 and coating layer 3 that covers core 2. The coating layer 3 contains a resin. The diameter of core 2 is in the range of 30-500 μm. The thickness of coating layer 3 is in the range of 5-100 μm. The coating layer 3 is melted at temperature in a range of 20° C. between 150 to 300° C., and the viscosity of coating layer 3 is in the range of 0.01-50 Pa-s. After solder balls 1 are set on terminal placement parts 13a in the main body of the electronic part, reflow is performed for solder balls 1. As a result, coating layer 3 is melted first, and core 2 descends under its own weight to come into contact with the terminal placement part. Core 2 is then melted, and core 2 and terminal placement part 13a are soldered and joined to each other.

This is a continuation of application Ser. No. 11/551,476 filed Oct. 20, 2006, the contents of which are herein incorporated by reference in its entirety, and which claims priority from Japanese application number 2005-305131 filed Oct. 20, 2005.

### FIELD OF THE INVENTION

The present invention pertains to a method for forming electronic parts using solder balls. In particular, the present invention pertains to a method for forming solder balls of a package for bare chip or surface assembly.

### BACKGROUND OF THE INVENTION

For surface assembly types of electronic parts, such as ball grid array (BGA) or chip scale package (CSP), solder balls are often used as terminals. In recent years, with the demand for higher assembly density of electronic parts has spurred progress in increasing the number of terminals and in reducing the terminal pitch of electronic parts. In order to realize this objective, the diameter of the solder balls used as terminals is reduced.

In the following, an example of the formation of terminals using solder balls in the prior art will be explained with reference to FIGS. 7-14. In this method, first of all, as shown in FIG. 7, electronic part main body (hereinafter to be referred to as the main body) 111 is prepared. This main body 111 has substrate 112, conductor layer 113, and solder resist layer 114. For example, substrate 112 contains prescribed elements and circuits formed using semiconductor manufacturing technology. Said conductor layer 113 is arranged on one surface (upper surface in the case shown in FIG. 7) 112a of substrate 112. This conductor layer 113 is connected to said element or circuit. Said solder resist layer 114 is arranged on surface 112a and the upper surface of conductor layer 113. Openings are formed in solder resist layer 114 above conductor layer 113 where the solder balls to be used as terminals are to be placed (hereinafter to be referred to as the terminal placement part) 113a is exposed. Then, after coating terminal placement part 113a with flux, not shown in the figure, solder paste 115P, for example, is applied by means of screen printing. FIG. 8 is a diagram illustrating the state in which flux and solder paste 115P have been applied to terminal placement part 113a.

Then, as shown in FIG. 9, solder ball suction holding fixture 120 is used to pick up and hold plural solder balls 101 from within container 106 containing solder balls 101 for use at the terminals of the electronic part. Said solder ball suction holding fixture 120 has plural suction holding holes 121 for accommodating solder balls 101, respectively, and suction path 122 connected to said suction holding holes 121. In said solder ball suction holding fixture 120, as the air in suction path 122 is drawn off with a vacuum pump, not shown in the figure, solder balls 101 are sucked up and held at suction holding holes 121, respectively, so that plural solder balls 101 are held. The configuration of the plural suction holding holes 121 corresponds to the configuration of the plural terminal placement parts 113a in main part 111. Ultrasonic vibration is applied to container 106 to prevent the plural solder balls 101 in container 106 from sticking to each other.

Then, as shown in FIG. 10, solder ball suction holding fixture 120 is positioned above main body 111 such that the plural solder balls 101 held by solder ball suction holding fixture 120 are positioned directly above plural terminal placement parts 113a, respectively.

Then, as shown in FIG. 11, the solder balls 101 held by solder ball suction holding fixture 120 are released, and solder balls 101 are carried onto terminal placement parts 113a, respectively. At this time, solder balls 101 become temporarily bonded to terminal placement parts 113a by means of solder paste 115P.

Then, as shown in FIG. 12, solder balls 101 and solder paste 115P are made to reflow, so that solder balls 101 and terminal placement parts 113a are solder bonded to each other. In this way, plural solder balls 101 become attached to main body 111. Also, solder paste 115P becomes solder layer 115 arranged around the periphery of the joint between solder balls 101 and terminal placement parts 113a.

Then, as shown in FIG. 13, for example, main body 111 having plural solder balls 101 attached to it is dipped in organic solvent 131 held in container 130 to remove the flux residue from main body 111.

As shown in FIG. 14, after performing the aforementioned operation, terminals using solder balls 101 are formed with respect to main body 111. The electronic part has main body 111 and terminals formed on main body 111.

In the prior art, technologies have been proposed for forming a thin coating layer on the solder balls for various purposes. For example, Patent Reference 1 disclosed a technology in which scratches and oxidation of the solder balls during transportation and the placement operation can be prevented, and at the same time, the solder balls can be released easily from the solder ball suction fixture. Here, the surface of the solder balls is uniformly coated with a lubricant, such as an aliphatic hydrocarbon base lubricant, higher aliphatic alcohol·higher fatty acid base lubricant, fatty acid amide base lubricant, metal soap base lubricant, fatty acid ester base lubricant, composite lubricant, etc. The thickness of the coating layer is about 1 Å (0.1 nm) to about 10 Å (1 nm).

Patent Reference 2 disclosed a technology in which a fluorine-containing resin is coated on the solder microballs to prevent them from bonding (making them hard to separate from each other) between the plural solder balls when the balls are in a container. The thickness of the coating layer is about 1-20 nm.

Patent Reference 3 disclosed a technology for forming a coating layer of an organic acid salt with respect to the solder powder that together with the flux forms the solder paste. The diameter of the grains of the solder powder is in the range of 10-100 μm, and the thickness of the coating layer is about 0.1-10 μm.

Patent Reference 1: Japanese Kokai Patent Application No. 2000-288771

Patent Reference 2: Japanese Kokai Patent Application No. 2004-160514

Patent Reference 3: Japanese Kokai Patent Application No. 2000-317682

The method for forming terminals in the prior art shown in FIGS. 7-14 has the following problems. First, as the number of the terminals is increased and the terminal pitch becomes smaller for the electronic part, the diameter of solder balls 101 becomes smaller, and the suction and holding holes 121 of solder ball suction holding fixture 120 also become correspondingly smaller. As a result, when solder ball suction holding fixture 120 is used to pick up plural solder balls 101, some suction and holding holes 121 do not hold solder balls 101. Before solder balls 101 are placed on terminal placement parts 113a, it is easy for solder balls 101 to fall from suction and holding holes 121. Also, as the number of terminal increases, the terminal pitch decreases, and the diameter of solder balls 101 becomes smaller, it may be impossible to set solder balls 101 at the correct positions on main body 111. Consequently, in the method of forming terminals of the prior art, in conjunction with an increase in the number of terminals, a reduction of the terminal pitch, and a decrease in the diameter of solder balls 101, defects can easily occur with respect to the placement of setting solder balls 101 on terminal placement parts 113a of main body 111. This is undesirable.

Also, in the method of forming terminals of the prior art, in conjunction with an increase in the number of terminals and a decrease in the terminal pitch, it becomes difficult to place solder paste 115P at the correct positions on main body 111.

Also, flux is a necessity in the method of forming terminals in the prior art. Consequently, it is necessary to have a process step of applying of the flux and a process step of removing the flux residue. At the same time, it is necessary to recover and process the organic solvent used in removing the flux residue.

Such problems cannot be solved by the technologies described in said Patent References 1-3, which also give no indication of a scheme to solve the problems.

The objective of the present invention is to solve the aforementioned problems of the prior art by providing an electronic part manufacturing method using solder balls characterized by the fact that it can prevent poor connections between the solder balls and the electronic parts, and to improve the reliability and yield.

### SUMMARY OF THE INVENTION

The present invention provides an electronic part manufacturing method characterized by the fact that it has the following process steps: a process step in which plural solder balls are prepared, with each solder ball being composed of a ball-shaped core made of solder and a coating layer that contains a resin having a melting point lower than the melting point of said coating layer; a process step in which said solder balls are placed at plural conductive regions formed on the electronic part; and a process step in which said plural solder balls are heated so that said coating layer is melted with a viscosity of 0.01-50 Pa-s, and the solder balls are reflow-connected to said conductive regions.

As a preferred scheme, when the solder balls are heated, the coating layer has a viscosity of 0.01-50 Pa-s. The solder balls are heated at about 150-300° C., and the metal plating of the coating layer is in a temperature range of at least 20° C. in the range of 150-300° C. In this case, preheating can be performed in order to ensure that solder balls can be easily bonded temporarily on the conductive regions.

The diameter of said core is in the range of 30-500 μm, and the thickness of said coating layer is in the range of 5-100 μm. Said coating layer contains a component that acts as a flux. For example, said coating layer contains an epoxy resin, and an imidazole base solidifying agent as the component acting as a flux. Also, the flux action refers to the action of removing the metal oxide film.

In said manufacturing method, when the solder balls are reflow-connected, the core of each makes contact with the conductive region due to melting of the coating layer, and the core is then soldered and joined to the conductive material in the conductive region. The side of said core facing the conductive region of the core is exposed when the coating layer has melted. Said coating layer spreads to the periphery of the joint between said core and said conductive material. The coating layer spreading to the periphery becomes a reinforcing layer for reinforcing the connected solder balls.

The solder balls can be connected to the electrodes formed on the principal surface of a semiconductor chip, and the solder balls can be connected to the conductive regions formed on the principal surface of a semiconductor package. In addition, the solder balls can be connected to the conductive regions formed on a wiring substrate. Said solder balls function as bump electrodes or bump terminals.

### BRIEF DESCRIPTION OF THE DRAWINGS

FIG. 1 is a cross section illustrating the core of the microballs in an embodiment of the present invention.

FIG. 2 is a cross section illustrating the microballs in an embodiment of the present invention.

FIG. 3 is a cross section illustrating a process step in the method of forming the terminals of the electronic part in an embodiment of the present invention.

FIG. 4 is a cross section illustrating the process step after the process step shown in FIG. 3.

FIG. 5 is a cross section illustrating the process step after the process step shown in FIG. 4.

FIG. 6 is a cross section illustrating the process step after the process step shown in FIG. 5.

FIG. 7 is a cross section illustrating a process step in the method for forming terminals of the prior art.

FIG. 8 is a cross section illustrating the process step after the process step shown in FIG. 7.

FIG. 9 is a cross section illustrating the process step after the process step shown in FIG. 8.

FIG. 10 is a cross section illustrating the process step after the process step shown in FIG. 9.

FIG. 11 is a cross section illustrating the process step after the process step shown in FIG. 10.

FIG. 12 is a cross section illustrating the process step after the process step shown in FIG. 11.

FIG. 13 is a cross section illustrating the process step after the process step shown in FIGS. 12.

FIG. 14 is a cross section illustrating the process step after the process step shown in FIG. 13.

### REFERENCE NUMBERS AND SYMBOLS AS SHOWN IN THE DRAWINGS

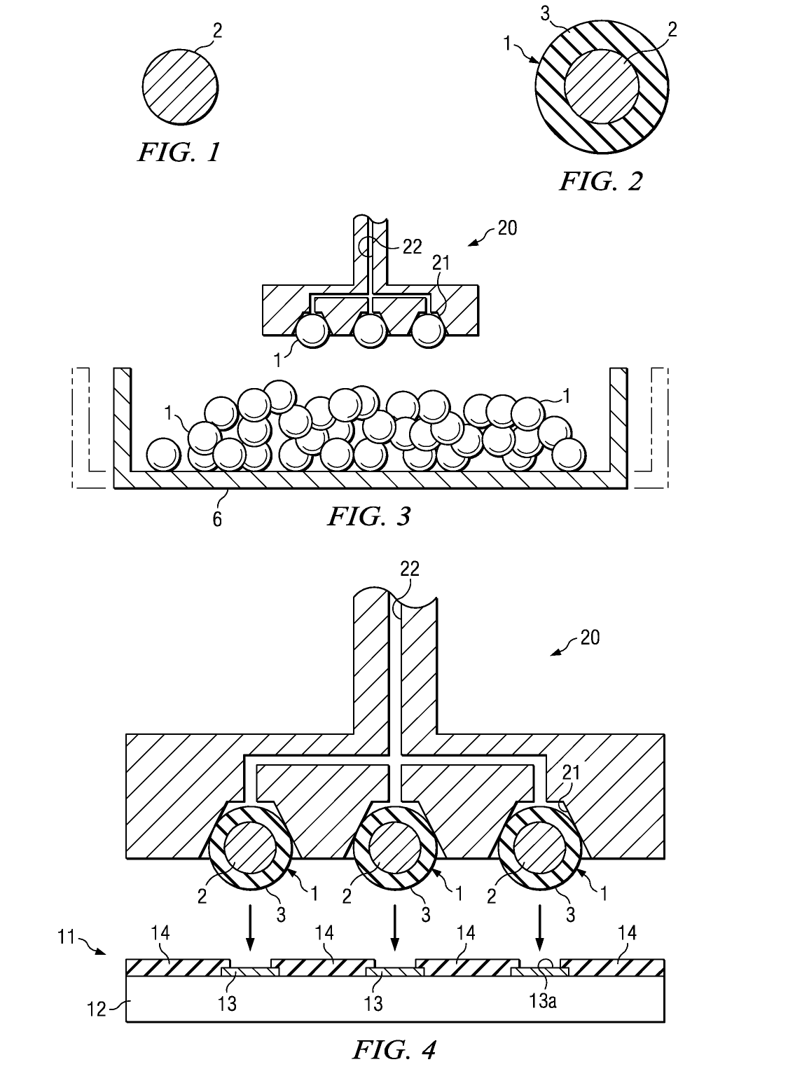

In the FIGS. 1 represents 2 a microball, a core, 3 a coating layer, 11 a main body of electronic part, 12 a substrate, 13 a conductor layer, 13a a terminal placement part, a solder resist layer, and 20 a microball suction holding fixture

### DESCRIPTION OF THE EMBODIMENTS

In the electronic part manufacturing method of the present invention, the solder balls are formed with each core covered with a coating having a melting point lower than the melting temperature of the core, and the solder balls are joined to the conductive regions of the electronic parts. Consequently, the operation can be performed easily when solder balls are sucked up and held by a suction holding fixture, and it is possible to alleviate defects in joining the solder balls to the electronic part. It is preferred for the thickness of the coating layer to be in the range of 5-100 μm while the diameter of the core is in the range of 30-500 μm, and the diameter of the microballs to be larger than that of the solder balls having a diameter equal to the diameter of the core. At this point, too, operability becomes easier, and at the same time, it is possible to form bumps or terminals identical to those created when solder balls having a diameter equal to that of the core are used.

Also, when the layer coating the solder balls contains a component acting as a flux, it is possible to use no flux and to form the terminals of the electronic part by removing the metal oxide film just like when flux was used. In addition, the coating layer that spreads to the periphery of the joint between the core and the conductive region in the reflow process step can easily become a reinforcing layer that reinforces the solder balls joined to the conductive regions after the reflow process step.

In the following, an embodiment of the present invention will be explained with reference to the figures. First, with reference to FIGS. 1 and 2, the microballs used in the method for forming terminals of the electronic part as well as their manufacturing method will be explained for an embodiment of the present invention. FIG. 1 is a cross section illustrating the core in a microball in this embodiment. FIG. 2 is a cross section illustrating the microball in the present embodiment. As shown in FIG. 2, microball 1 in this embodiment has ball-shaped solder core 2 and coating layer 3 that covers core 2. The solder that forms core 2 may be a solder free of lead, or a solder containing lead. Said coating layer 3 contains a resin. The diameter of core 2 is in the range of 30-500 μm. The thickness of coating layer 3 is in the range of 5-100 μm.

Also, coating layer 3 is melted at a temperature in a 20° C. range within the range of 150-300° C., with the viscosity of coating layer 3 falling in the range of 0.01-50 Pa-s. This condition is defined so that coating layer 3 is also melted at the temperature at which the solder that forms core 2 is melted. Also, the melting point of lead-free solder is usually in the range of about 260-280° C., and the melting point of the solder containing lead is in the range of about 220-240° C.

Also, if the viscosity of coating layer 3 does meet the aforementioned condition, the resin contained in coating layer 3 can be either thermosetting resin or thermoplastic resin. Also, coating layer 3 can be made of a resin composition containing resin and other materials. In this case, coating layer 3 can contain epoxy resin and an imidazole base solidifying agent as the component acting as a flux.

Also, coating layer 3 is not fluid at room temperature (25° C.). Also, the tackiness (adhesion) of coating layer 3 at room temperature (25° C.) should be sufficiently low so that the coating layers 3 of plural microballs 1 do not stick to each other.

In the following, the method of manufacturing microballs 1 will be explained. First, as shown in FIG. 1, cores 2 are formed. The method for forming cores 2 is the same as that for forming the solder balls in the prior art. Then, as shown in FIG. 2, coating layer 3 is formed for each core 2. For example, coating layer 3 may be formed using the following method, just like the method for forming a coating layer described in Patent Reference 3. In this method, first, the resin or resin composition that forms coating layer 3 is dissolved in an organic solvent to form a solution. The solution is then blown in atomized form by a blower onto the continuously falling cores 2. Hot air is then blown by a hot air drier arranged below the blower on falling cores 2 with the solution attached to them. As a result, the organic solvent is evaporated from the surface of each core 2. Consequently, a layer made of the resin or resin composition that forms coating layer 3 is formed on the surface of each core 2. Also, by repeating this blown solution treatment of cores 2 and said evaporation of organic solvent from the surface of each core 2, it is possible to form coating layer 3 with the desired thickness. Also, the method for forming coating layer 3 is not limited to the aforementioned method.

In the following, the method for forming terminals of the electronic part in the present embodiment will be explained with reference to FIGS. 3-6. In this method, first, as shown in FIG. 3, microball suction holding fixture 20 is used to pick up and hold plural microballs 1 for terminals of the electronic part from container 6 that contains plural microballs 1. Said microball suction holding fixture 20 has plural suction holding holes 21 that respectively accommodate said microballs 1, and suction path 22 connected to said suction holding holes 21. Then, by sucking out the air in suction path 22 in said microball suction holding fixture 20 with a vacuum pump not shown in the figure, a microball 1 is sucked up and held by each of the suction holding holes 21, so that plural microballs 1 are held. The configuration of suction holding holes 21 corresponds to the configuration of the plural terminal placement parts on the main body of the electronic part. Ultrasonic waves are applied on container 6 to prevent sticking between the plural microballs 1 in container 6.

Then, as shown in FIG. 4, electronic part main body (hereinafter to be referred to as the main body) 11 is prepared. This main body 11 has substrate 12, conductor layer 13 and solder resist layer 14. For example, substrate 12 may contain the prescribed elements or circuits formed using semiconductor manufacturing technology. Said conductor layer 13 is arranged on one surface (the upper surface in the case shown in FIG. 4) 12a of substrate 12. Said conductor layer 13 is connected to said elements or circuits. Said solder resist layer 14 is arranged on surface 12a and the upper surface of conductor layer 13. Openings are formed in solder resist layer 14 above conductor layer 13 to expose conductive regions (hereinafter to be referred to as terminal placement parts) 13a where terminals using the microballs are to be placed.

Then, microball suction holding fixture 20 is positioned above main body 11 such that plural microballs 1 held by microball suction holding fixture 20 are positioned directly above plural terminal placement parts 13a. Then microballs 1 held by microball suction holding fixture 20 are released, and the various microballs 1 are respectively set on said terminal placement parts 13a. Also, it is preferred that main body 11 be heated at a temperature (for example, 150° C.) at which coating layer 3 melts a little before microballs 1 are set on terminal placement parts 13a. As a result, when microballs 1 are set on terminal placement parts 13a, coating layer 3 is melted a little, and microballs 1 will be temporarily bonded to terminal placement parts 13a.

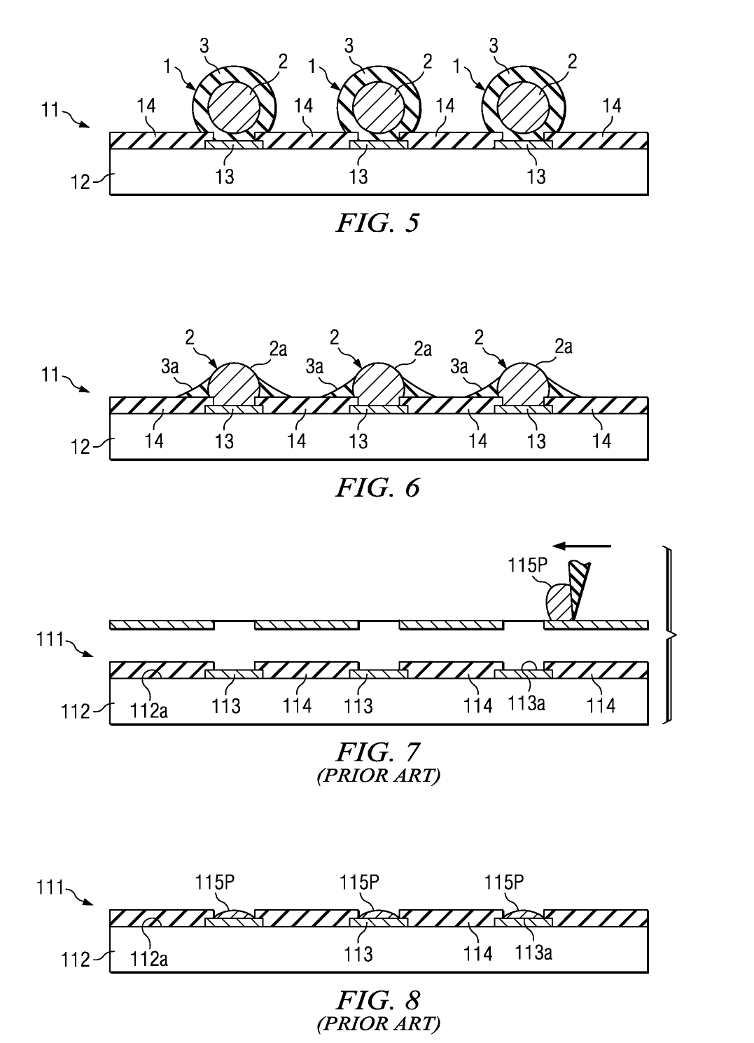

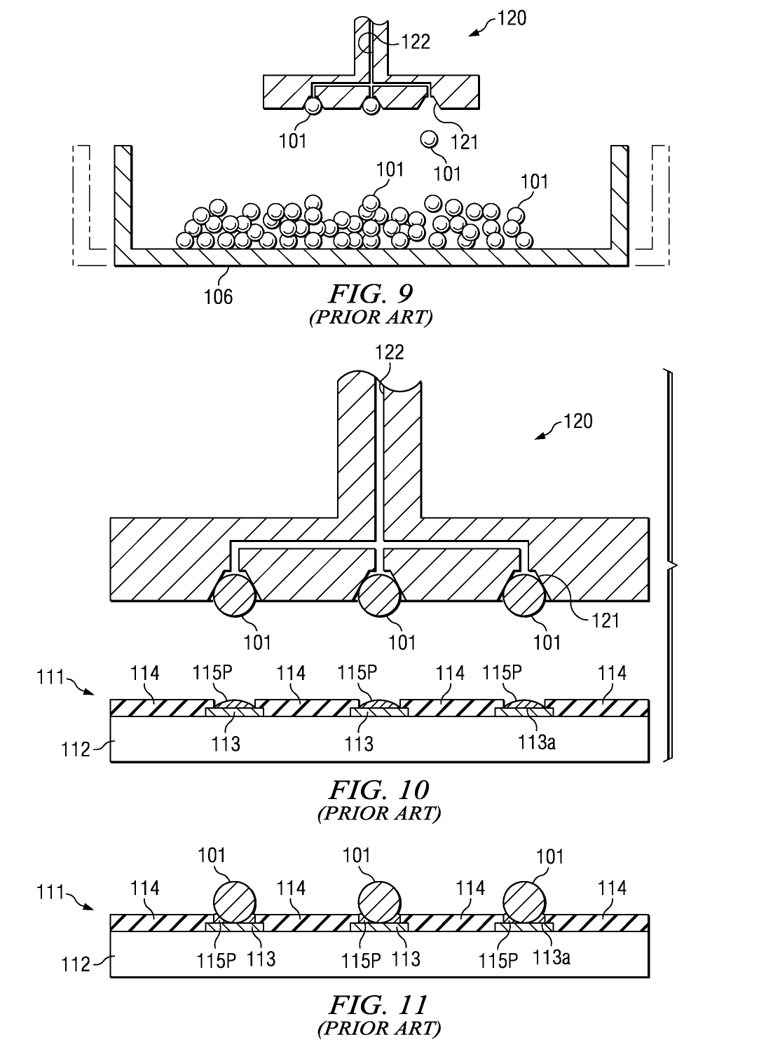

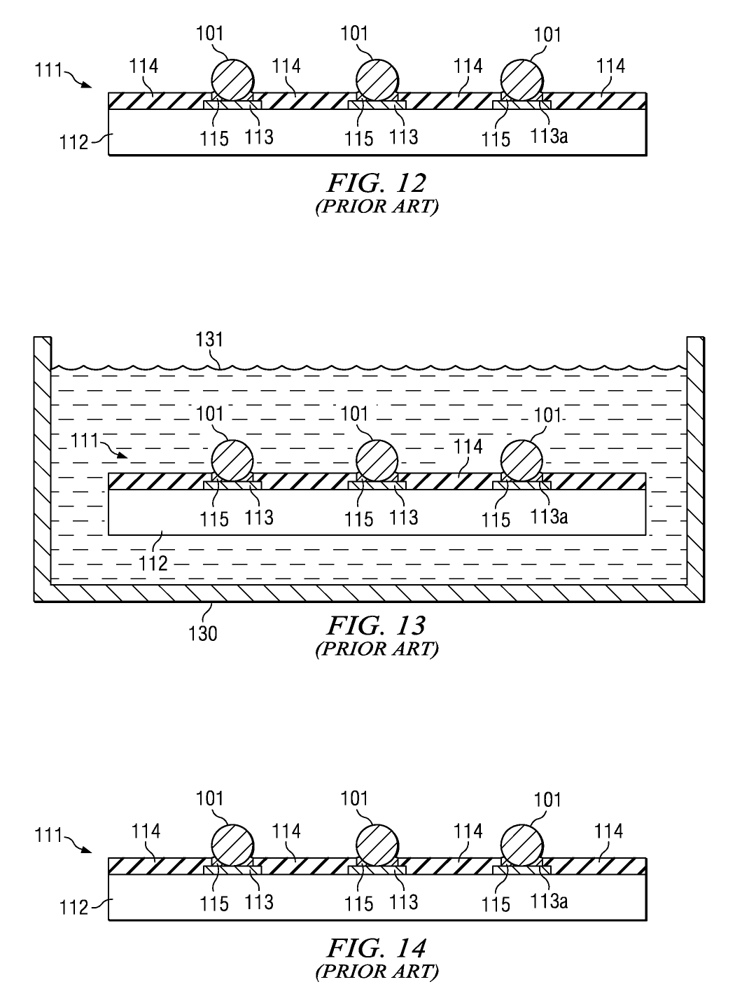

Then, as shown in FIGS. 5 and 6, reflow is performed for microballs 1. In the following, this process step will be referred to as the reflow process step. FIG. 5 is a diagram illustrating the steps during the reflow operation. FIG. 6 shows the final step in the reflow operation. For example, the reflow time is 10-30 sec. The temperature of reflow is the temperature at which the solder that forms core 2 melts. More specifically, when the solder that forms core 2 is made of a lead-free solder, the reflow temperature is at, for example, 260-280° C. On the other hand, when the solder that forms core 2 is a solder containing lead, the temperature of reflow is, for example, 220-240° C.

As shown in FIG. 5, in the reflow operation, coating layer 3 is melted first. As a result, core 2 descends under its own weight. Core 2 then comes into contact with terminal placement part 13a. Then, as shown in FIG. 6, a certain portion of coating layer 3 flows out due to its low viscosity, and the top portion 2a of core 2 is exposed. The flowed-out coating layer 3a spreads to the periphery of the joint portion between core 2 and terminal placement part 13a, and it acts as a reinforcing layer of the joint portion of core 2. In addition, core 2 is melted, and core 2 and terminal placement part 13a are soldered and joined. In this way, a bump terminal for the electronic part is formed with core 2. After the reflow operation, top portions 2a positioned on the outer peripheral surface of core 2 on the side opposite to terminal placement part 13a are exposed to the outside without being covered by coating layer 3.

When coating layer 3 contains a component acting as a flux when coating layer 3 is melted in the reflow operation, the component acting as a flux removes the metal oxide film on the surface of terminal placement parts 13a. As a result, the wettability between core 2 and terminal placement part 13a is improved, so that the two portions will bond well.

When the resin contained in coating layer 3 is a thermoplastic resin, coating layer 3 is solidified as the temperature of coating layer 3 drops after the reflow operation and it becomes a reinforcing layer for reinforcing the terminal using core 2. When the resin contained in coating layer 3 is a thermosetting resin, coating layer 3 is solidified by performing heat treatment of the electronic part for a relatively long time at a temperature lower than the melting temperature of the solder that forms core 2. As a result, coating layer 3 becomes the reinforcing layer for reinforcing the terminal using core 2. The temperature of the heat treatment for solidifying coating layer 3 is in the range of, for example, 150-200° C., and the heat treatment time is, for example, in the range of 30-60 min.

Said electronic part has main body 11 and terminals formed on main body 11. For example, this electronic part is assembled on an assembly substrate. In this case, the terminals are connected to the conductor layer on the assembly substrate. On the outer peripheral surface of core 2 that forms a terminal, a portion of the surface positioned opposite from terminal placement part 13a is exposed to the outside without being covered by coating layer 3. As a result, when the terminal is connected on the conductor layer to the assembly substrate, coating layer 3 does not hamper the connection.

As explained above, in this embodiment, each microball 1 is composed of ball-shaped core 2 made of solder, and coating layer 3 that covers core 2. The diameter of core 2 is in the range of 30-500 μm, and the thickness of coating layer 3 is in the range of 5-100 μm. Said microball 1 makes it possible to form the same terminal as that formed when a solder ball with a diameter equal to that of core 2 is used.

On the other hand, the diameter of microball 1 is larger than that of the solder ball having the same diameter as that of core 2. Consequently, microball 1 in the present embodiment can be handled more easily than the solder ball having the same diameter as that of core 2. More specifically, in the present embodiment, the size of suction holding holes 21 of microball suction holding fixture 20 can fit the size of microballs 1 with a diameter larger than cores 2. As a result, in the present embodiment, even when the diameter of core 2 becomes smaller with an increase in the number of terminals on the electronic part and a reduction in the terminal pitch, there is no need for suction holding holes 21 to be very small. Consequently, in this embodiment, when microball suction holding fixture 20 is used to pick up plural microballs 1, it is possible to prevent the presence of suction holding holes 21 that do not hold microballs 1 and falling off of microballs 1 from suction holding holes 21 before microballs 1 are placed on terminal placement parts 13a can be prevented. Also, in this embodiment, because microball 1 is larger than core 2 that forms the terminal, it is easy to set microball 1 at the correct position on main body 11. As explained above, according to the present embodiment, it is possible to prevent the generation of defects pertaining to placement of microballs 1 on terminal placement parts 13a in main body 11.

Also, in the present embodiment, there is no need to have a process step for coating with solder paste in the method for forming terminals of the electronic part, so that the number of process steps can be reduced.

Also, in this embodiment, in the method for forming terminals of the electronic part, there is no need for the process step of coating with flux and the process step of removing the flux residue, so that there is no need to recover and process the organic solvent used in removing the flux residue. Consequently, in the present embodiment, in the method for forming the terminals of the electronic part, it is possible to have fewer process steps. In the present embodiment, there can be a component acting as a flux in coating layer 3. In this case, it is possible for no flux to be used in removing the metal oxide film to form terminals of the electronic part, achieving the same result as when flux is used.

Also, in this embodiment, in the method for forming terminals of the electronic part, a melted coating layer is present in the periphery of the terminal placement parts, so that said coating layer can serve as a reinforcing layer.

The present invention is not limited to the aforementioned embodiment. Various changes can be made. For example, the coating layer on the microballs can be made of two or more layers of different materials. In this case, the outermost layer in the coating layer can be a layer for reducing the tackiness of the coating layer. In addition, according to the present invention, microballs can be used to form bumps for the electrodes of a bare chip, the terminals of a semiconductor package, the land electrodes of a printed board, etc.

What is claimed is:

1. An electronic device; comprising:
a substrate;
a conductive terminal placement part on the substrate;
a solder member having a bottom portion bonded on the conductive terminal placement part and a top portion; and
a resin layer coating on the bottom portion of the solder member and the top portion of the solder member free of the resin layer coating.

2. A method of manufacturing an electronic device; comprising:
placing a micro ball having a core inside a resin coating on a conductive terminal placement part over a substrate;
melting the resin coating at a first temperature;
melting the core at a second temperature higher than the first temperature;
forming a metallurgical junction of the core at the conductive terminal placement part; and
covering a lower portion of the metallurgical junction and uncovering a upper portion of the metallurgical junction with the melt resin coating.
